(19) United States
(12) Patent Application Publication
(10) Pub. No.: US 2006/0007927 A1
(43) Pub. Date: Jan. 12, 2006

(54) Transmission frame structure for control communication network of distributed control system for nuclear power plant

(76) Inventors: Sung Woo Lee, Daejeon (KR); Eung Se Oh, Daejeon (KR); Sung Il Song, Daejeon (KR); Kwi Yil Gwak, Daejeon (KR); Seok Gon Kim, Daejeon (KR)

Correspondence Address: CANTOR COLBURN, LLP, 55 GRIFFIN ROAD SOUTH, BLOOMFIELD, CT, 06002, US

(21) Appl. No.: 11/103,738

(22) Filed: Apr. 12, 2005

(30) Foreign Application Priority Data
Apr. 12, 2004 (KR) 2004-0025021

(51) Int. Cl. G01R 31/08

(52) U.S. Cl. 370/389; 370/242

(57) ABSTRACT

A transmission frame structure for use in a control communication network allows all process control stations contained in the control communication network to share monitoring/control information received from a field communication network or an information communication network, and properly copes with faulty operations of channels (i.e., ring-shaped lines) or process control stations for use in the control communication network. The transmission frame structure of a control communication network for use in a nuclear-power-plant distributed control system which broadcasts data received from a node having transmission authority to all nodes via a bypass line, and allows a ring accelerator to detour the data and to isolate an erroneous station from normal stations, includes a transmission frame. The transmission frame includes: a destination address for performing the broadcasting operation; a source address for recording a source node address (ID) therein; a type/length field for classifying frames into a control data frame and a network management event frame; a network management (NM_TYPE) field which is valid only when it is designated by type/length field, and performs different roles according to network management event frame types; a Seq&Ver field for including the number of transmissions of a data frame and frame upgrade version information; a NS_ID field for recording number information of a node equal to the next token reception node, and being used when one station transmits a token to the next station; a data field having a predetermined maximum size of 1 kbyte, for including not only general control information according to a value of the type/length field, but also 7 event frames such as a token frame; and a CRC (Cyclic Redundancy Code) field for inspecting the presence or absence of a CRC error, whereby the transmission frame operates the communication network, solves a malfunction or error of the communication network, and recovers the communication network.

### BACKGROUND OF THE INVENTION

1. Field of the Invention

The present invention relates to a method for constructing a transmission frame of a control communication network of a distributed control system for use in a nuclear power plant (hereinafter referred to as a nuclear-power-plant distributed control system), which can efficiently use the control communication network of the nuclear-power-plant distributed control system in which real-time characteristics and reliability are the most highly regarded. More particularly, the present invention relates to a transmission frame structure for use in a control communication network, which allows all process control stations contained in the control communication network to share monitoring/control information received from a field communication network or an information communication network, and properly copes with faulty operations of channels (i.e., ring-shaped lines) or process control stations for use in the control communication network.

2. Description of the Related Art

Typically, a distributed control system can efficiently control a plurality of processors in power plants or the petrochemical industry, and can also allow the processors to share data with each other in the power plants or petroleum-chemical industries. A communication network for use in the nuclear-power-plant distributed control system includes an information communication network, a control communication network, and a field communication network. The information communication network interconnects a plurality of stations distributed in a wide area, such that it can allow the plurality of stations to share a variety of information with each other. The control communication network acts as a transmission medium to allow a plurality of field control devices to share data with each other.

The field communication network allows the control communication network to directly communicate with field control devices. In the case of controlling a plurality of systems distributed into a power plant field, the control communication network enables data communication between distributed control devices and other devices, and also allows the distributed control device to share data with the other devices, such that the control communication network is generally considered to be a very important component. The control communication network performs a communication function using a 100M Ethernet. A plurality of process control stations are connected to the control communication network, and are connected to the field communication network via the above-mentioned process control stations.

Industrial control communication networks include a common field bus communication network, an IEEE 802.3 (CSMA/CD; Ethernet) communication network, an IEEE 802.4 (Token Bus) communication network, an IEEE 802.5 (Token Ring) communication network, and other communication networks using unique protocols developed by individual production companies, etc. Although the field bus is used to perform a control operation, it should be noted that the field bus is generally used as a low-level communication network rather than a high-level communication network. The Ethernet controls a plurality of stations contained to competitively access the communication network, such that it is unable to satisfy real-time characteristics and reliability needed to control a power plant. The token-bus communication scheme and the token-ring communication scheme allow individual stations to sequentially transmit data to solve unreliability of the Ethernet, such that they can be used for real-time data transmission. However, the present invention exemplarily discloses a specific case in which a conventional 100M Ethernet card is used, such that an Ethernet transmission frame will hereinafter be described. FIG. 1 shows an Ethernet transmission frame structure in which a CSMA/CD access method from among MAC (Medium Access Control) protocols based on IEEE 802 series indicative of the most popular LAN (Local Area Network) is used.

As shown in FIG. 1, a preamble 100 is a first area of an 802.3 frame, and includes 7 bytes in which 0 and 1 are repeated, such that it informs a reception system of frame arrival. A Start Frame Delimiter (SFD) area 101 acts as an indicator for designating the beginning of the frame, and includes only 1 byte. A Destination Address (DA) area 102 is assigned the next destination address having 6 bytes. A Source Address (SA) area 103 is indicative of an address of a source indicative of a packet transmission object, and includes 6 bytes. A Length PDU area 104 is indicative of a length of data to be received soon, and includes 2 bytes.

A Data and Padding area 105 has a frame length having 46˜1500 bytes, includes an 802.2 (Local Link Control) frame. A field of the Data and Padding area 105 is indicative of a unit which can be configured in the form of a module and can also be removed. Therefore, if a large amount of communication data is generated, a network access method for use in the Ethernet may suffer data collision or transmission failure problems due to the occurrences of unexpected time delay and competition.

A field bus from among industrial control communication protocols uses different protocols according to system application objects, and is generally designed to properly control field devices, such that it is improper to be used as a control communication protocol of a nuclear-power-plant distributed control system acting as a large-sized process control system. Also, a plurality of stations contained in the communication network competitively access the communication network over the Ethernet, such that the Ethernet is unable to satisfy real-time characteristics and reliability required to control the power plant. Also, it is difficult to apply an application algorithm, which can permit a fault associated with a communication system of the nuclear-power-plant distributed control system, and can also manage a communication network, to the Ethernet. Particularly, the Ethernet is unable to properly cope with a line failure or station failure of the communication system.

In this manner, the conventional Ethernet 802.3 communication scheme controls a plurality of stations contained in a communication network to competitively access the communication network, such that it cannot satisfy real-time characteristics and reliability required to control a large-capacity nuclear-power-plant distributed control system. Although the IEEE 802.4 (Token Bus) communication scheme and the IEEE 802.5 (Token Ring) communication scheme are widely used to implement FA (Factory Automation) and process control, they cannot satisfy real-time characteristics requested by a communication system for use in a nuclear-power-plant distributed control system, cannot perform defect permission and duplexing operations capable of flexibly operating a communication network, and cannot accommodate an application algorithm capable of resolving a malfunction.

Therefore, the present invention provides a method for constructing a transmission frame when operating a large-capacity nuclear-power-plant distributed control system to which a maximum of 64 stations are accessible, such that the transmission frame structure controls the distributed control system to receive update information from a field control device, and allows all stations contained in a control communication network to share data in real time, and controls an erroneous control communication system to be normally operated by conducting fault permission of the control communication system.

### SUMMARY OF THE INVENTION

Therefore, the present invention has been made in view of the above problems, and it is an object of the invention to provide a transmission frame structure for use in a large-capacity nuclear-power-plant distributed control system using a 100M Ethernet-based communication network acting as a control communication network, such that the transmission frame structure receives monitoring/control information from a field communication network or information communication network over the 100M Ethernet communication network, controls all process control stations contained in the control communication network to share data in real time, and properly copes with faulty operations of a control communication system node or the communication network.

It is another object of the present invention to provide a transmission frame structure for additionally adding a network management field acting as a transmission frame core field to a frame field, in which the network management field can manage token scheduling information for pre-designating a station to which data transmission authority will be assigned, and can isolate a faulty communication line from a normal communication line.

In accordance with the present invention, the above and other objects can be accomplished by the provision of a transmission frame structure of a control communication network for use in a nuclear-power-plant distributed control system which broadcasts data received from a node having transmission authority to all nodes via a bypass line, and allows a ring accelerator to pass the data by a roundabout way and to isolate an erroneous station from normal stations, comprising: a transmission frame. The transmission frame includes: a destination address for performing the broadcasting operation; a source address for recording a source node address (ID) therein; a type/length field for classifying frames into a control data frame and a network management event frame; a network management (NM_TYPE) field which is valid only when it is designated by type/length field, and performs different roles according to network management event frame types; a Seq&Ver field for including the number of transmissions of a data frame and frame upgrade version information; a NS_ID field for recording number information of a node equal to the next token reception node, and being used when one station transmits a token to the next station; a data field having a predetermined maximum size of 1 kbyte, for including not only general control information according to a value of the type/length field, but also 7 event frames (i.e., NM_TOKEN_FRAME, NM_DUAL_CH_CHECK_FRAME, NM_DUAL_CH_READY_FRAME, NM_NM_LINK_CHECK_FRAME, NM_NM_NODE_FAIL_FRAME, NM_NODE_CHECK_FRAME, and NM_TX_MODE_FRAME frames) such as a token frame; and a CRC (Cyclic Redundancy Code) field for inspecting the presence or absence of a CRC error, whereby the transmission frame operates the communication network, solves a malfunction or error of the communication network, and recovers the communication network.

### BRIEF DESCRIPTION OF THE DRAWINGS

The above objects, and other features and advantages of the present invention will become more apparent after reading the following detailed description when taken in conjunction with the drawings, in which:

FIG. 1 shows an Ethernet transmission frame structure;

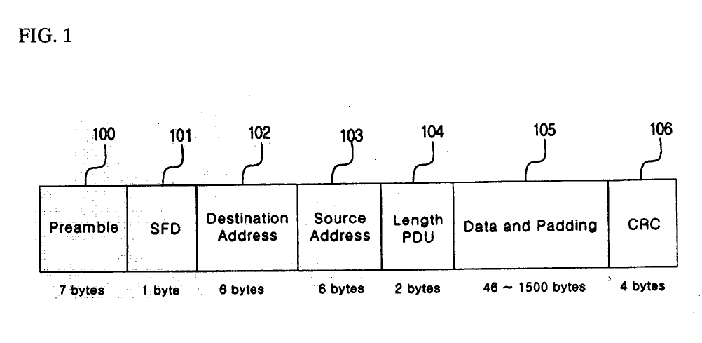

FIG. 2 shows a control communication network structure and a data transmission structure;

FIG. 3 shows a structural diagram illustrating an apparatus for improving topology of a control communication network;

FIG. 4 shows a control communication network management algorithm and a state transition diagram according to the present invention; and

FIG. 5 shows a transmission frame structure for controlling a nuclear-power-plant distributed control system according to the present invention.

### DESCRIPTION OF THE PREFERRED EMBODIMENTS

Now, preferred embodiments of the present invention will be described in detail with reference to the annexed drawings. In the drawings, the same or similar elements are denoted by the same reference numerals even though they are depicted in different drawings. In the following description, a detailed description of known functions and configurations incorporated herein will be omitted when it may make the subject matter of the present invention rather unclear.

The present invention relates to a method for constructing a transmission frame of a control communication network of a nuclear-power-plant distributed control system, which can efficiently use the control communication network of the nuclear-power-plant distributed control system in which real-time characteristics and reliability are the most highly regarded. The transmission frame structure allows all process control stations contained in the control communication network to share monitoring/control information received from a field communication network or an information communication network, and properly copes with faulty operations of channels (i.e., ring-shaped lines) or process control stations for use in the control communication network.

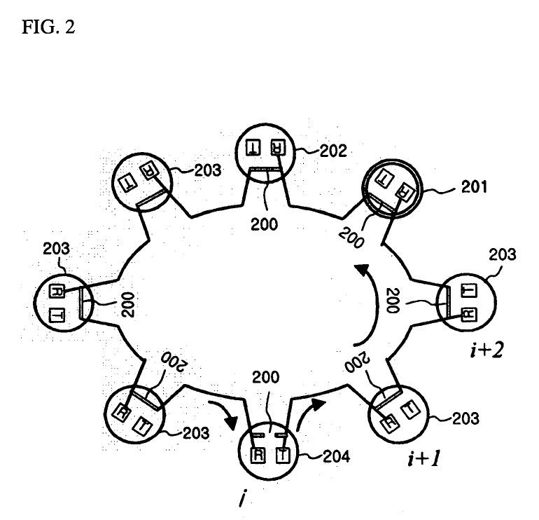

FIG. 2 shows an exemplary control communication network for use in a nuclear-power-plant distributed control system. Although the control communication network is indicative of a ring-shaped communication network as shown in FIG. 2, it is substantially considered to be a bus-shaped communication network. Therefore, if a node 204 having transmission authority transmits data, the data is broadcast to all nodes 201, 202, 203, and 204 over a bypass line. Each of the nodes 201˜204 includes a transmitter T, a receiver R, and a buffer. A ring acceleration unit 200 selectively performs data transmission or data broadcasting. The data successively moves counterclockwise from a node (i) having transmission authority to other nodes i+1 and i+2.

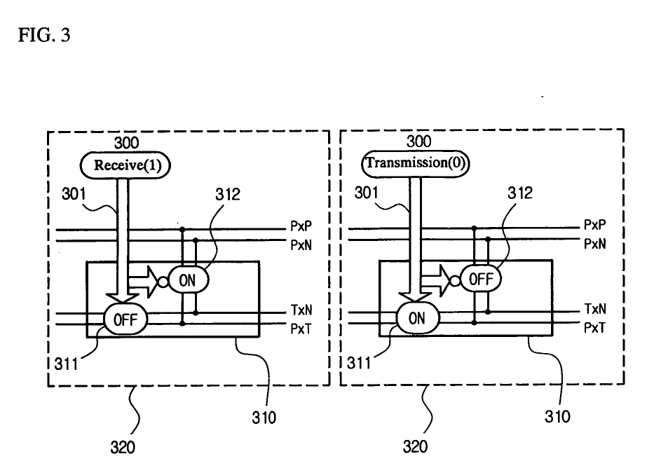

The ring acceleration unit 120 controls transmission data to pass by a roundabout way, and is also used to isolate a faulty station from a normal station as can be seen from FIG. 3. A medium control scheme for use in the inventive communication network is established by tokens. A predetermined manager node 201 generates an initial token or manages the flow of tokens.

The manager node 201 inspects the flow of tokens and data of an overall communication network, such that it discriminates a specific node 204 (i) having current transmission authority from among a plurality of nodes, and monitors whether individual nodes preferably perform data transmission/reception. In order to resolve a malfunction of the manager node 201, the next node 202 acting as a manager backup node periodically monitors soundness of the manager node 201. If a malfunction or error occurs in the manager node 201, the manager backup node 202 detects the malfunction or error, takes manager authority from the manager node 201, and isolates the erroneous manager node 211 from a communication network, such that it can normally manage the overall communication network.

FIG. 3 is a structural diagram illustrating a ring acceleration unit 200 shown in FIG. 2. As shown in FIG. 3, a transmission line is denoted by TxN and TxP, and a reception line is denoted by RxN and RxP. If a controller 300 determines a reception mode 320 or a transmission mode 330, a switch is operated according to the determined mode, such that the reception mode 320 receives data and at the same time transmits reception data to the next node via a bypass line connected to an analog switch 312, and the transmission mode 330 switches off the analog switch 312 and at the same time transmits data to be transmitted to a neighboring node. The controller 300 is implemented with software, and can transmit a control signal to the control signal line 301 to perform a switch operation between the reception mode 320 and the transmission mode 330.

Two analog switches 311 and 312 contained in an analog switching unit 310 are properly operated according to state information of the controller 300. In the case of the reception mode 320, the analog switch 312 is switched on and the other analog switch 311 is switched off when the controller 300 selects the reception mode 320, input data is applied to the reception mode 320, and at the same time is transmitted to a neighboring node via the analog switch 312. In the case of the transmission mode 330, the analog switch 312 is switched off and the other analog switch 311 is switched on when the controller 300 selects the transmission mode 330, such that data to be transmitted can be transmitted to a neighboring node.

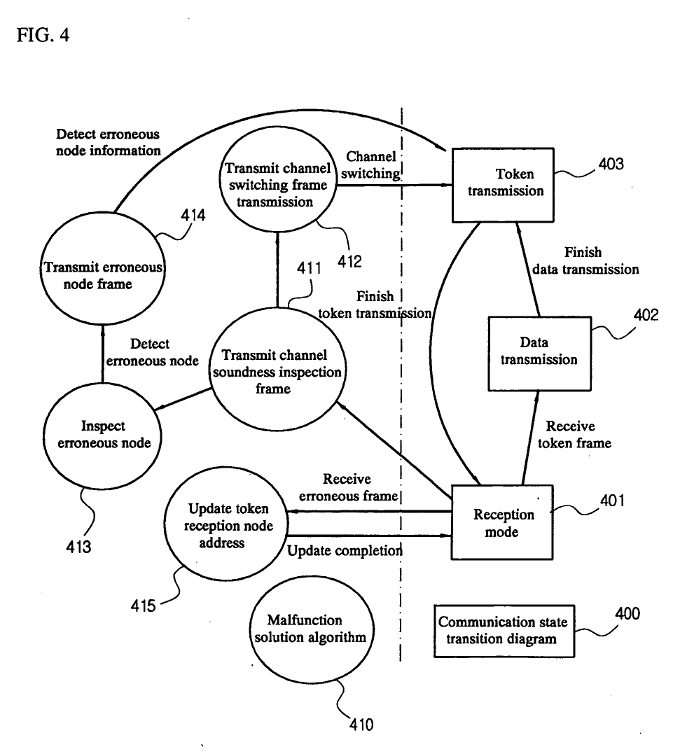

FIG. 4 shows a data transmission state transition diagram 400 of a control communication network manager node and a malfunction solution algorithm 410 performed by the manager node when faulty operations of lines or stations occur in a communication system. If all stations in a reception mode 401 receive tokens, they perform data transmission 402. If data transmission 402 is completed, all stations perform token transmission, and return to the reception mode 401.

If timer interruption occurs due to a malfunction of the communication system, a channel soundness inspection frame is transmitted as denoted by 411, and determines the presence or absence of a channel (i.e., a line) error. If the channel error occurs, a channel switching frame is transmitted as denoted by 412, such that it performs channel switching. If a station (i.e., a node) error occurs, an erroneous station is inspected as denoted by 413, a frame of the inspected erroneous station is transmitted to all stations as denoted by 414, token transmission is performed, and the process returns to the reception mode 401. Also, if all stations receive information of an erroneous station from a manager station during the reception mode 401, they update an address of the erroneous station as denoted by 415, and do not transmit data to the erroneous station.

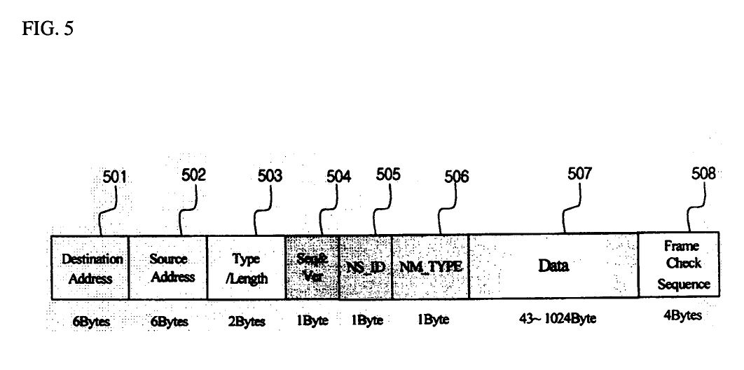

FIG. 5 shows a transmission frame structure for use in a data link layer capable of performing data communication over a control communication network. A token passing method for controlling a token of a ring-shaped transmission line to circulate in all nodes according to a predetermined order is generally used as a communication scheme of the control communication network. Provided individual stations of the control communication network occupy a token, this indicates that each station has transmission authority. If a node having a token finishes data transmission, it gives the next node the token, such that the next node can perform data transmission.

An algorithm for operating a communication network, solving a malfunction or error of the communication network, and recovering the communication network is performed by the transmission frame shown in FIG. 5. A destination address 501 (i.e., a destination node address) having 6 bytes is used to perform a broadcasting operation. A source address 502 (i.e., a source node address) having 6 bytes is used to record an address ID of a transmission node. A type/length field having 2 bytes is used to discriminate a frame type. There are two kinds of frames, i.e., a data frame for a control operation and an event frame for network management. Different values are assigned to the type/length field 503 for use in the data frame and the other type/length field 503 for use in each of seven event frames (See the following Table 1) having token transmission.

If the type/length field 503 designates the event frame, the network management field (NM_TYPE) 506 must designate one event frame from among seven event frames. In more detail, the network management field 506 having 1 byte is valid only when the type/length field 503 designates the network management field 506 itself, and its role is determined according to NM_TYPE information shown in Table 1.

TABLE 1
Control communication network event frames

| | Network management event frames | | |
|---|---|---|---|
| Numbers | (NM_TYPE) | Usages | Remarks |
| 601 | NM_TOKEN_FRAME | Token | Transmission authority |
| | | | possession |
| 602 | NM_DUAL_CH_CHECK_FRAME | Inspect backup channel | Channel duplexing |
| 603 | NM_DUAL_CH_READY_FRAME | Prepare backup channel | Channel duplexing |
| | | Switching | |
| 604 | NM_NM_LINK_CHECK_FRAME | Inspect Communication | Periodic inspection |
| | | network link | |
| 605 | NM_NM_NODE_FAIL_FRAME | Notify node (station) | Erroneous node |
| | | Malfunction | Information |
| 606 | NM_NODE_CHECK_FRAME | Inspect node (station) | Confirm Erroneous |
| | | | node recovery |
| 607 | NM_TX_MODE_FRAME | Notify switching to | Isolate erroneous node |
| | | transmission mode | and return |

A Seq&Ver field 504 having 1 byte includes the number of transmissions of a data frame, and also includes frame upgrade version information. A NS_ID field 505 having 1 byte includes number information of a node indicative of the next token reception node, such that it is used when one station transmits a token to the next station.

A data field 507 having 43˜1024 bytes has a predetermined maximum size of 1 kbyte, and may include general control information according to a value of the type/length field 503. Also, the data field 507 may include seven event frames such as a token frame. A CRC (Cyclic Redundancy Code) field 508 having 4 bytes is used to inspect the presence or absence of a CRC error.

The Seq&Ver field 504, the NS_ID field 505, and the NM_TYPE field 506 contained in the inventive transmission frame are newly proposed to operate a control communication network of a nuclear-power-plant distributed control system according to the present invention. The destination address node 501, the source address node 502, the type/length field 503, the data field 507, and the CDC field 508 perform functions similar to those in construction fields of the conventional Ethernet transmission frame. However, the data field 507 can perform a data transmission function as in the conventional Ethernet transmission frame, and can include event frame information therein, differently from the conventional Ethernet transmission frame. The inventive transmission frame can accommodate data capacity having a maximum of 1024 (1K) bytes, whereas the Ethernet transmission frame can accommodate data capacity having a maximum of 1500 bytes.

As shown in Table 1, the NM_TOKEN_FRAME 601 unit is indicative of a token frame needed to operate a network. A general station receives the NM_TOKEN_FRAME 601, gains transmission authority, and broadcasts its own data. The NM_DUAL_CH_CHECK_FRAME 602 unit determines whether a link of a channel to be switched is alive when a current channel is in an abnormal state, such that it determines the presence or absence of the channel link soundness. The NM_DUAL_CH_READY_FRAME 603 unit informs general nodes of a preparation state of communication switching to a backup channel, when a main channel is in an abnormal state.

The NM_LINK_CHECK FRAME 604 unit periodically determines whether a backup line (i.e., a link) indicative of a communication network backup channel is alive whenever it receives a token predetermined reception times. The NM_NODE_FAIL_FRAME 605 unit transmits new token scheduling information to all nodes when a node is isolated or encounters a malfunction or error, such that it indicates an address of the abnormal node. The NM_NODE_CHECK_FRAME 606 unit periodically determines whether the node isolated by the malfunction or error returns to a normal state. If the node recovers from the malfunction or error, the NM_NODE CHECK_FRAME 606 unit is re-included in the communication network, such that it can be assigned transmission authority.

The NM_TX_MODE_FRAME 607 unit automatically operates (i.e., switches on) a bypass line of a topology improvement device in association with the erroneous node, such that it can always maintain a reception (Rx) mode. If the erroneous node returns to a normal state, the NM_TX_MODE_FRAME 607 unit does not maintain the reception (Rx) mode any more, such that it can enable the erroneous node to perform data transmission (Tx).

The present invention provides a unique transmission frame without using transmission frames for use in conventional communication networks (i.e., an Ethernet communication network, a token bus communication network, and a token ring communication network), and applies the transmission frame to a communication system. The transmission frame according to the present invention is characterized in that a network management field, which manages token scheduling information capable of pre-designating a station to which data transmission authority will be assigned and isolates a faulty communication line from a normal communication line, is additionally provided, and is then added to a frame field.

In other words, the transmission frame according to the present invention can perform data and token transmission using only one frame structure, whereas a token ring or an Fiber Distributed Data Interface (FDDI) includes a data frame and a token frame separated from each other. The network management field includes a total of seven event frames. A token frame is one of the event frames, and is included in the network management field.

As apparent from the above description, a method for constructing a transmission frame according to the present invention can properly cope with faulty operations of lines or stations of a communication system incapable of being included in IEEE 802-series communication networks, receives update information from a field control device when operating a nuclear-power-plant distributed control system to which a maximum of 64 stations are accessible, quickly transmits the received update information to all stations contained in a control communication network, and controls the system in real time, resulting in increased stability and reliability of the system.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

1. A transmission frame structure of a control communication network for use in a nuclear-power-plant distributed control system which broadcasts data received from a node having transmission authority to all nodes via bypass line, and allows a ring accelerator to pass the data by a roundabout way and to isolate an erroneous station from normal stations, comprising:
a transmission frame including:
a destination address for performing the broadcasting operation;
a source address for recording a source node address (ID) therein;
a type/length field for classifying frames into a control data frame and a network management even frame;
a network management (NM_TYPE) field which is valid only when it is designated by type/length field, and performs different roles according to network management event frame types;
a Seq&Ver field for including the number of transmissions of a data frame and frame upgrade version information;
a NS_ID field for recording number information of a node equal to the next token reception node, and being used when one station transmits a token to the next station;
a data field having predetermined maximum size 1 kbyte, for including not only general control information according to a value of the type/length field, but also 7 event frames (i.e., NM_TOKEN_FRAME, NM_DUAL_CH_CHECK_FRAME, NM_DUAL_CH_READY_FRAME, NM_NM_LINK_CHECK_FRAME, NM_NM_NODE_FAIL_FRAME, NM_NODE_CHECK_FRAME, and NM_TX_MODE_FRAME frames) such as a token frame; and
a CRC (Cyclic Redundancy Code) field for inspecting the presence or absence of a CRC error,
whereby the transmission frame operates the communication network, solves a malfunction of the communication network, and recovers the communication network.

2. The transmission frame structure according to claim 1, wherein the transmission frame structure performs data communication using the NM_TYPE field including the 7 event frames for network management, the type/length field for discriminating between the data frame and the event frames, and the NS_ID field including token scheduling information.

3. The transmission frame structure according claim 1, wherein the event frames contained in the NM_TYPE field controls the type/length field to indicate a token frame without using an additional token transmission, and then perform an event control operation.

4. The transmission frame structure according to claim 1, wherein the NM_DUAL_CH_CHECK_FRAME frame indicative of a backup channel check frame determines the presence or absence of soundness of a channel to be switched, if a current channel is in an abnormal state.

5. The transmission frame structure according to claim 1, wherein the NM_DUAL_CH_READY_FRAME frame informs general nodes of a preparation state of communication switching to a backup channel, if a main channel is in an abnormal state.

6. The transmission frame structure according to claim 1, wherein the NM_LINK_CHECK_FRAME frame periodically determines whether a backup line (i.e., a link) indicative of a communication network backup channel is alive whenever it receives a token predetermined reception times.

7. The transmission frame structure according to claim 1, wherein the NM_NODE_FAIL_FRAME frame transmits new token scheduling information to all nodes when a node is isolated or encounters a malfunction or error, and thus indicates an address of an abnormal node.

8. The transmission frame structure according to claim 1, wherein the NM_NODE_CHECK_FRAME frame periodically determines whether a node isolated by a malfunction or error returns to a normal state, such that it is re-included in the comminication network when the node recovers from the malfunction or error, and is then assigned transmission authority.

9. The transmission frame structure according to claim 1, wherein the NM_TX_MODE_FRAME frame releases reception mode maintenance of aN erroneous node when the erroneous node is restored to a normal state, such that the node can perform data transmission (Tx) upon receiving the token.

10. The transmission frame structure according to claim 2, wherein the event frames contained in the NM_TYPE field controls the type/length field to indicate a token frame without using an additional token transmission, and then perform an event control operation.
